(19) United States
(12) Patent Application Publication
(10) Pub. No.: US 2015/0204918 A1
(43) Pub. Date: Jul. 23, 2015

(54) MAGNETIZING INRUSH CURRENT DETECTION METHOD, MAGNETIZING INRUSH CURRENT RESTRAINT METHOD AND DEVICE

(71) Applicant: SIEMENS AKTIENGESELLSCHAFT, MUENCHEN (DE)

(72) Inventors: Shu De Chen, Wuhan (CN); Wei Chen, Wuhan (CN); Di Jun Gao, Nanjing (CN); Jin Hui Li, Nanjing (CN); Lei Ming Qin, Nanjing (CN); Chun Rao, Wuhan (CN); Min Yang, Nanjing (CN)

(21) Appl. No.: 14/425,104

(22) PCT Filed: Aug. 6, 2013
(86) PCT No.: PCT/EP2013/066451

§ 371 Date: Mar. 2, 2015

(30) Foreign Application Priority Data
Aug. 31, 2012 (CN) 201210320886.9

(51) Int. Cl. G01R 19/10; G01R 25/00; H02H 7/045

(52) U.S. Cl. CPC G01R 19/10; H02H 7/045; G01R 25/00

(57) ABSTRACT

A method for detecting a magnetizing inrush current of a transformer includes the steps of obtaining a difference current for each AC phase of a transformer and calculating, for each AC phase, at least two factors for waveform symmetry recognition, on the basis of the difference currents obtained within one period. For each type of factor, one obtains the maximum value of the three factors corresponding to the three AC phases, to serve as a maximum phase factor of that factor. Based on the maximum phase factor obtained, a waveform symmetry recognition algorithm is used to calculate a corresponding waveform symmetry parameter, and if the waveform symmetry parameter meets a requirement for waveform asymmetry, then it is determined that a magnetizing inrush current has occurred. A device for protecting the transformer is further provided.

### TECHNICAL FIELD

The present invention relates to transformer protection technology in general, and in particular to a method and device for detecting the magnetizing inrush current which occurs when a transformer is switched on with no load, and a magnetizing inrush current restraint method and device.

### BACKGROUND ART

In an electrical system, a large transient current will occur when a transformer is switched on with no load, for instance 6-8 times the rated current of the transformer. This large transient current which occurs when a transformer is switched on with no load is what is known as “magnetizing inrush current” in the art. As a result, there is a strong likelihood that the occurrence of a magnetizing inrush current when the transformer is switched on with no load will erroneously trigger the differential protection action of the transformer, so that the transformer automatically trips in the instant after it is switched on.

The main reason for the occurrence of “magnetizing inrush current” is that when a transformer is switched on with no load, the iron core thereof rapidly reaches severe saturation while the magnetizing impedance is greatly reduced, the result being a magnetizing inrush current of large amplitude. A characteristic of magnetizing inrush current is the very large value of the current surge, which can reach 6-8 times or even 10 times the rated current of the transformer. Furthermore, a large part of the magnetizing inrush current is made up of a DC component and high-order harmonic components, the waveforms thereof being mostly biased towards one side of the time axis. Moreover, the waveform of the magnetizing inrush current may be intermittent. In general, the magnetizing inrush current falls to a value typically no more than 0.25-0.5 of the rated current within 0.5-1 s of occurring, but in the case of large-capacity transformers, the total attenuation time thereof may be as long as several seconds.

To avoid erroneous activation of transformer differential protection as a result of the magnetizing inrush current, the main transformer protection configured in current electrical systems generally includes differential protection based on restraint of the second harmonic associated with the magnetizing inrush current. In response to the requirement for the main protection to have a dual function, many factories not only configure differential protection based on second harmonic restraint, but also make use of waveform characteristics to configure differential protection in which inrush current restraint is achieved on the basis of the interruption angle principle or waveform symmetry principle, etc. When the interruption angle principle is used in microcomputer protection, the high requirements it places on hardware make the implementation method rather difficult. The criterion for inrush current restraint based on the waveform symmetry principle has a simple structure and places lower requirements on hardware, and is therefore more suited to being used as the basis for main transformer protection which is different from second harmonic restraint and works in conjunction with differential protection.

Chinese patent application CN1182297A has disclosed a method for distinguishing magnetizing inrush current based on waveform symmetry. The method compares the values of two successive half-waves at sampling points to determine whether the current waveform is symmetric. Symmetry indicates a fault current; asymmetry indicates a magnetizing inrush current.

### CONTENT OF THE INVENTION

One object of the present invention is to propose a novel method and device for detecting a magnetizing inrush current in a transformer, and a corresponding method and device for differential protection blocking in a transformer, in order to recognize magnetizing inrush currents more accurately.

According to one aspect of the present invention, a magnetizing inrush current detection method for a transformer is proposed, comprising: obtaining a difference current iₓ(n) for each AC phase of the transformer; determining whether the difference current iₓ(n) of any one of the three AC phases exceeds a predetermined current threshold; if the difference current iₓ(n) of any AC phase exceeds the predetermined current threshold, then calculating, for each AC phase, at least two factors (Ax, Bx) for waveform symmetry recognition, on the basis of the difference currents of that AC phase obtained within one period; for each type of factor, obtaining the maximum value of the three factors corresponding to the three AC phases, to serve as a maximum phase factor of that factor; based on the maximum phase factor obtained, using a waveform symmetry recognition algorithm to calculate a corresponding waveform symmetry parameter kₘₐₓ; if the waveform symmetry parameter kₘₐₓ meets a requirement for waveform asymmetry and the difference current iₓ(n) of any AC phase exceeds a predetermined current threshold, then determining that a magnetizing inrush current has occurred. Preferably, the step of calculating at least two factors further comprises: filtering out a DC component of the sampled difference current iₓ(n), to obtain a difference value i′ₓ(n) of the difference current.

According to a preferred embodiment of the present invention, the factors used for waveform symmetry recognition comprise: a first factor (Ax), which is a function of the sum of two difference current difference values separated by half a period; and a second factor (Bx), which is a function of the difference between two difference current difference values separated by half a period. Preferably, the function used for the first factor (Ax) is the cumulative value of the modulus of said sum over half a period; the function used for the second factor (Bx) is the cumulative value of the modulus of said difference over half a period. Even more preferably, the waveform symmetry parameter kₘₐₓ is the maximum phase factor of the first factor (Ax) divided by the maximum phase factor of the second factor (Bx). The difference current difference value i′ₓ(n) is found by a forward difference method.

According to another aspect of the present invention, a magnetizing inrush current restraint method for a transformer is proposed, comprising: determining by the above method whether the current flowing through the transformer at the present time is a magnetizing inrush current; if it is a magnetizing inrush current, then blocking differential protection of the transformer.

According to another aspect of the present invention, a transformer protection device for realizing the above method is further proposed. The device comprises: an acquisition unit, for obtaining a difference current iₓ(n) for each AC phase flowing through the transformer; a first judgment unit, for determining whether the difference current iₓ(n) of any one of the three AC phases exceeds a predetermined current threshold; a factor calculation unit, for calculating at least two factors for waveform symmetry recognition for each AC phase, on the basis of difference currents iₓ(n) sampled within one period; a maximum value determination unit, for obtaining the maximum value of the three factors corresponding to the three AC phases for each type of factor, to serve as a maximum phase factor (Amax, Bmax) of that factor; a symmetry parameter acquisition unit, for calculating a corresponding waveform symmetry parameter kₘₐₓ according to said waveform symmetry recognition, based on the maximum phase factor obtained (Amax, Bmax); and a second judgment unit, for determining that a magnetizing inrush current has occurred if the waveform symmetry parameter kₘₐₓ meets the requirement for waveform asymmetry and the first judgment unit gives a positive result. Preferably, the factor calculation unit further comprises: a filter unit, for filtering out a DC component from the sampled difference current, so as to obtain a difference value of the difference current; and the factor calculation unit calculates the at least two factors on the basis of the difference value of the difference current.

Preferably, the factors used for waveform symmetry recognition comprise: a first factor, which is the cumulative sum over an entire half-cycle of the sum of two difference current difference values separated by half a period; and a second factor, which is the cumulative sum over an entire half-cycle of the difference between two difference current difference values separated by half a period. Preferably, the device further comprises a blocking unit, for blocking differential protection of the transformer when the judgment unit determines that a magnetizing inrush current has occurred.

According to another aspect of the present invention, a device for transformer protection is proposed, comprising: a microprocessor, for performing operations or processing according to commands; a memory, for storing commands which can be executed by the microprocessor, the commands being used to realize the method described when executed by the microprocessor. A computer program product, comprising: code which can be executed by a machine, the code being used to realize the method as claimed in any one of claims 1-7 when executed by the machine. A computer recording medium, comprising: a machine-recordable/readable medium on which machine-executable code is stored, the code being used to realize the method described above when executed by a machine.

Since the magnetizing inrush current detection method proposed by the present invention takes full account of the relationships among the three AC phases, more accurate inrush current recognition is achieved when this method is used. Secondly, the present invention uses a waveform symmetry algorithm based on sampled difference currents (preferably difference values of difference currents); this algorithm is able to correctly judge whether a magnetizing inrush current has occurred in a shorter time than other algorithms. Furthermore, since the present invention preferably uses difference currents from which DC components have been filtered out to calculate waveform symmetry factors, interference from DC components is avoided, so that the accuracy of recognition is higher. In addition, in the present invention, differential protection is blocked if the occurrence of a magnetizing inrush current is determined, and permitted otherwise; this logic can ensure reliable operation of differential protection more effectively. Moreover, using the method of the present invention enables rapid cut-off within one cycle when faults of all kinds occur. Also, when the second harmonic content of the magnetizing inrush current in a particular phase is less than 15%, a blocking flag can similarly be issued. In the method proposed by the present invention, since the existence of a fault phase causes the denominator to remain relatively high, the waveform symmetry parameter kₘₐₓ falls rapidly below a blocking constant value. When the system impedance is very high, if a single phase is grounded on the star side or an inter-phase fault occurs between two phases on the delta side, the method proposed in the present invention is still capable of operation, and so protection is still able to operate correctly.

In summary, the criterion described above can act quickly and correctly when all kinds of faults occur, and a blocking flag can be reliably set in the event of a magnetizing inrush current. Thus the present solution has improved performance in terms of recognizing inrush currents and distinguishing faults.

### DESCRIPTION OF THE ACCOMPANYING DRAWINGS

The object, characteristics, features and advantages of the present invention will be made more obvious by the following detailed description, which makes reference to the accompanying drawings.

FIGS. 1A-1C show typical waveforms of magnetizing inrush currents occurring in three AC phases A, B and C by way of example;

FIG. 2 shows a flow chart for magnetizing inrush current detection according to one embodiment of the present invention by way of example;

FIG. 3 shows a logic diagram for magnetizing inrush current restraint according to one embodiment of the present invention by way of example;

FIGS. 4A-4C show the waveform of a magnetizing inrush current, the variation of the corresponding waveform symmetry parameter and the variation of the second harmonic according to one embodiment of the present invention by way of example;

FIGS. 5A-5C show the waveform of a fault inrush current, the variation of the corresponding waveform symmetry parameter and the variation of the second harmonic according to another embodiment of the present invention by way of example;

FIG. 6 shows a block diagram of the structure of a transformer protection device according to another embodiment of the present invention by way of example.

### PARTICULAR EMBODIMENTS

Various embodiments of the present invention will be described below with reference to the accompanying drawings.

The following description will facilitate understanding of the above-mentioned advantages of the present invention.

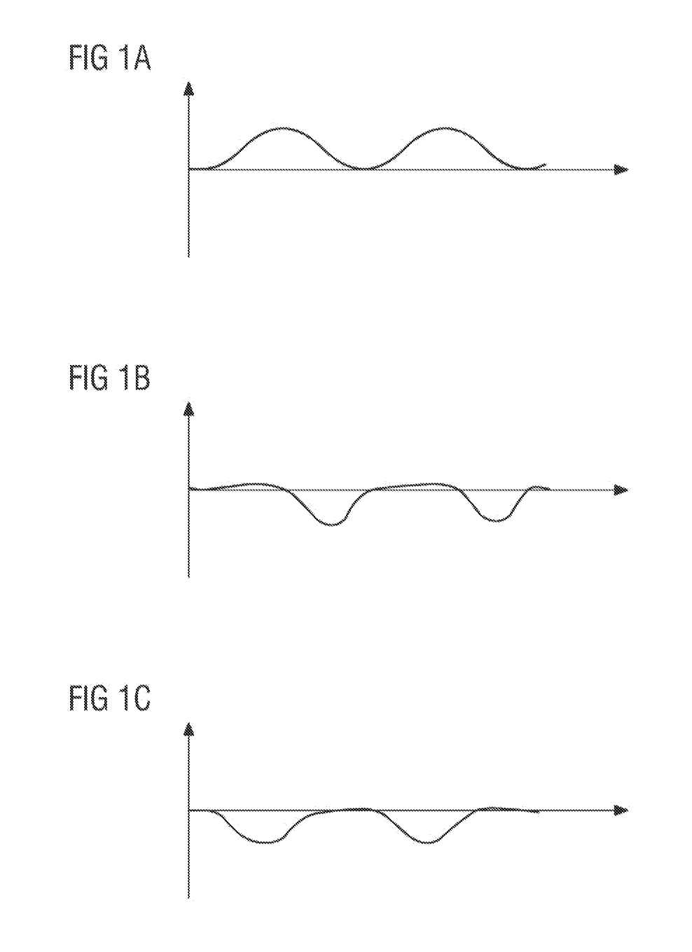

FIGS. 1A-1C show typical waveforms of magnetizing inrush currents occurring in three AC phases a, b and c of a three-phase transformer by way of example. By studying the characteristics of the magnetizing inrush current waveforms with reference to FIG. 1, it can be determined that the magnetizing inrush currents have the following characteristics.

(1) When a transformer is switched on with no load, whether an inrush current arises and the size of such an inrush current is related to the phase angle at the time of switch-on, the magnetizing inrush current being greatest for phase angles α=0 and α=π at switch-on.

(2) The magnetizing inrush currents in the three phases will be different, because there is a 120° phase difference between the voltages of the three phases.

(3) The magnetizing inrush current in a particular phase may no longer deviate from one side of the time axis, becoming a so-called “symmetric” inrush current. The other two phases are still asymmetric inrush currents which deviate from one side of the time axis. The value of the symmetric inrush current is comparatively small. Non-periodic attenuation components still make up a large part of the asymmetric inrush currents, but the non-periodic component in the symmetric inrush current is comparatively small.

(4) Transformer operating records show that the second harmonic may make up a comparatively small proportion of the magnetizing inrush current in one of the three phases, less than 15%.

(5) The waveforms of the magnetizing inrush currents in the three phases are still intermittent, but the interruption angles thereof are significantly reduced compared with a single-phase transformer inrush current; moreover, the interruption angle is smallest in the case of the symmetric inrush current.

(6) It can be seen from the above three diagrams that a magnetizing inrush current is generally asymmetric over ¼ of a cycle or more.

Based on the above analysis of magnetizing inrush currents, the inventors of the present application propose a novel method for detecting a magnetizing inrush current, i.e. a maximum phase analysis method based on waveform symmetry. Overall, in view of the differences evident in the magnetizing inrush current across the three phases, the inventors of the present application point out that it is better to consider the characteristics of the currents in the three phases overall than to simply consider whether the waveform in each phase is symmetric individually. Based on this thinking, the inventors of the present application point out that during the process of estimating whether a waveform is symmetric, the maximum value of the factors corresponding to the three phases should be selected for each of the different factors (e.g. Ax and Bx) used to calculate the waveform symmetry factor k. A waveform symmetry parameter Kmax calculated by such a method can comprehensively reflect the manifestation of the magnetizing inrush current in the three phases, and thereby prevent erroneous judgments caused by testing each phase separately. Here, the waveform symmetry parameter kₘₐₓ is a parameter used to describe the asymmetry of a current waveform; a higher value of kₘₐₓ implies more marked asymmetry.

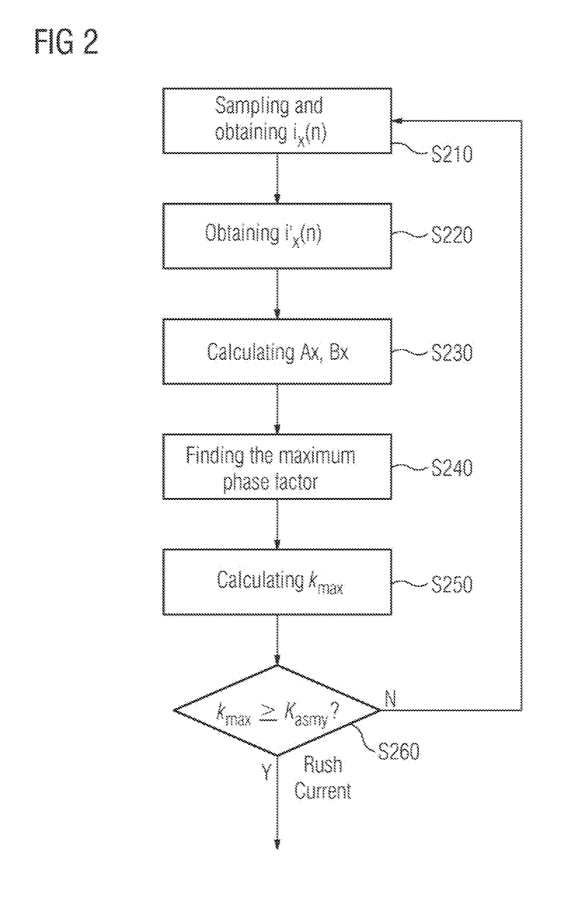

FIG. 2 shows a flow chart of a method for inrush current detection according to a preferred embodiment of the present invention by way of example.

As FIG. 2 shows, the inrush current detection method starts with step S210. In step S210, a difference current iₓ(n), where x=a, b, c, is first obtained for each AC phase of a three-phase transformer, wherein a, b and c each represent one AC phase. In step S220, preferably, the sampled difference current of each AC phase is filtered, so that a DC component is filtered out from the sampled current. Here, step S220 is optional. When the judgment conditions for waveform asymmetry are different, step S220 may be omitted. The aim of performing step S220 is to obtain the amount of change in current.

Specifically, step S220 may employ a forward difference method. For example, in one embodiment, suppose that the data window width is one period plus 1 sampling point, giving a data window width of N+1 points, where N is the number of sampling points in each period. Therefore the filtered difference current is the difference value of the difference current, and can be expressed as:

iₓ′(n)=iₓ(n)−iₓ(n−1) (1)

Depending on the actual situation, if the number of sampling points in one period is sufficiently large, then the sampled value i(n) of the difference current at the present time minus the value at a sampling point spaced therefrom in the forward direction by one or more sampling points, such as i(n−M) where M=2, 3 . . . , can be chosen for the forward difference described above. In certain situations, a backward difference method may also be used.

In step S230, two factors Aₓ and B_{X} for waveform symmetry recognition are calculated for each AC phase a, b and c. In this embodiment, the value of the n^{th} point in the current half-period in the data window is set as i′(n), while the value of the corresponding point in the previous half-period as

$${i}_{x}^{′} ( n - \frac{N}{2} ) ;$$

then

$$\begin{matrix}{A}_{x} ( n ) = {i}_{x}^{′} ( n ) + {i}_{x}^{′} ( n - \frac{N}{2} ) & ( 2 ) \\ {B}_{x} ( n ) = {i}_{x}^{′} ( n ) - {i}_{x}^{′} ( n - \frac{N}{2} ) & ( 3 )\end{matrix}$$

Aₓ(n) and Bₓ(n) are factors of a waveform symmetry recognition algorithm. According to formulas (2) and (3), if the waveform is symmetric (a sine wave), then

$${i}_{x}^{′} ( n ) \approx - {i}_{x}^{′} ( n - \frac{N}{2} ) ,$$

hence Aₓ(n)≈0. At the same time, Bₓ(n)≈2i′ₓ(n). In other words,

$$k = \frac{{A}_{x} ( n )}{{B}_{x} ( n )} \approx 0.$$

In contrast, if the waveform is not symmetric, then

$$k = \frac{{A}_{x} ( n )}{{B}_{x} ( n )}$$

is far greater than zero. Preferably, in this embodiment, in order to make recognition more accurate, A_{X}(n) and B_{X}(n) must be further subjected to the following processing, to obtain:

$${A}_{x} = {\sum }_{n = 0}^{\frac{N}{2} - 1} \vert {A}_{x} ( n ) \vert , \\ {B}_{x} = {\sum }_{n = 0}^{\frac{N}{2} - 1} \vert {B}_{x} ( n ) \vert , \\ x = a , b , c$$

Here, the form of Aₓ and Bₓ is schematic. Both the number of factors and the form they take may vary with different waveform symmetry recognition methods. For example,

$${A}_{x} = {\sum }_{n = 0}^{\frac{N}{2} - 1} {A}_{x}^{2} ( n ) ;$$

alternatively, an accumulation operation may be performed, over an entire period for instance. Alternatively, if the proportion of the difference current sample made up by a high-frequency component is taken as the basis for assessing waveform distortion, then factor Aₓ may be replaced by the size of the high-frequency component, while the factor Bₓ may be replaced by the size of the fundamental wave component in the difference current. In other situations, the number of factors may also be greater than two.

In step S240, for each type of factor Aₓ and Bₓ, the maximum value of the three factors corresponding to the three AC phases is found, i.e. Max(Aₐ, A_{b}, A_{c}) and Max(Bₐ, B_{b}, B_{c}) are found. The maximum value obtained for each type of factor is called the maximum phase factor, e.g. Aₘₐₓ or Bₘₐₓ.

In step S250, a wave symmetry parameter is calculated on the basis of the maximum phase factors calculated. In this embodiment,

$${k}_{max} = \frac{{A}_{max}}{{B}_{max}} = \frac{Max \{ {\sum }_{n = 0}^{\frac{N}{2} - 1} \vert {A}_{a} ( n ) \vert , {\sum }_{n = 0}^{\frac{N}{2} - 1} \vert {A}_{b} ( n ) \vert , {\sum }_{n = 0}^{\frac{N}{2} - 1} \vert {A}_{c} ( n ) \vert \}}{Max \{ {\sum }_{n = 0}^{\frac{N}{2} - 1} \vert {B}_{a} ( n ) \vert , {\sum }_{n = 0}^{\frac{N}{2} - 1} \vert {B}_{b} ( n ) \vert , {\sum }_{n = 0}^{\frac{N}{2} - 1} \vert {B}_{c} ( n ) \vert \}} \qquad ( 4 )$$

Formula (4) merely shows one method for calculating the waveform symmetry parameter kₘₐₓ by way of example. The method used for calculating the waveform symmetry parameter will vary depending on the waveform symmetry recognition method used. For instance, in the above example in which waveform distortion is assessed on the basis of the proportion made up by a high-frequency component, the waveform symmetry parameter kₘₐₓ may also be

$$\frac{Max ( {I}_{2 a} , {I}_{2 b} , {I}_{2 c} )}{Max ( {I}_{1 a} , {I}_{1 b} , {I}_{1 c} )} ,$$

where I₂ is the second harmonic component and I₁ is the fundamental wave component. Of course, in Formula (4) of this embodiment, only the difference values of the difference currents have been used, without taking into account the second harmonic component.

In step S260, it is determined whether kₘₐₓ is greater than a predetermined threshold K_{asmy}. If kₘₐₓ≧K_{asmy}, then the waveform is asymmetric, otherwise the waveform is symmetric, i.e. is not a magnetizing inrush current. Here, K_{asmy} can be set on the basis of empirical values. K_{asmy} is set as any suitable non-zero value according to actual requirements. In this embodiment, the value of K_{asmy} is preferably 0.2-0.8, even more preferably 0.3-0.4. K_{asmy} may be determined by a number of methods. For example, the maximum value of the ratio kₘₐₓ may be calculated by varying the phase angle at switch-on with no load, using a simulation model; this value can then be taken as the upper limit of K_{asmy}. Next, various internal transformer faults are simulated and calculations carried out thereon, to verify whether the chosen value of K_{asmy} meets the requirements.

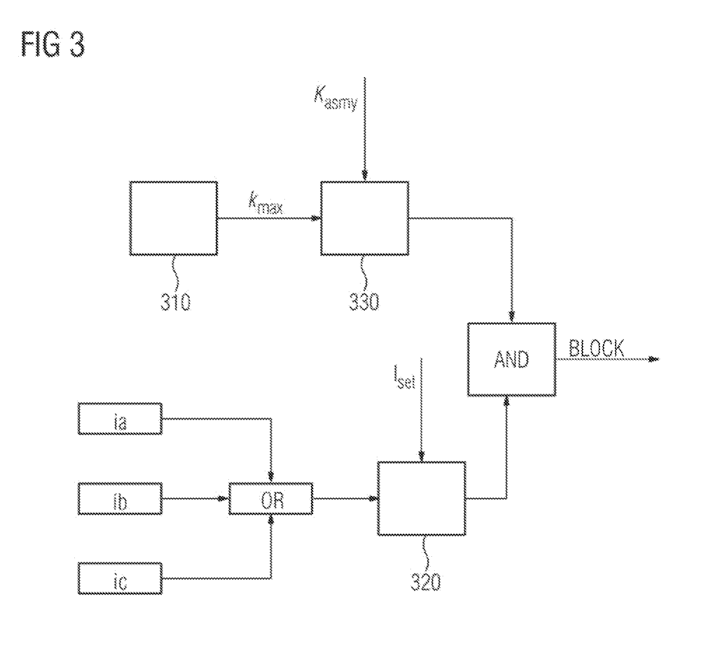

FIG. 3 shows by way of example a logic diagram for realizing inrush current restraint on the basis of the inrush current detection method shown in FIG. 2. As FIG. 3 shows, preferably, it is determined whether the difference current of at least one of the three phases is greater than a given current threshold Iₛₑₜ. Iₛₑₜ is preferably 0.1*I_{N}-0.3*I_{N}, for instance, where I_{N} is the rated current of the transformer. If the difference current of any phase is greater than Iₛₑₜ and the waveform asymmetry condition (kₘₐₓ≧K_{asmy}) is satisfied, this indicates a magnetizing inrush current, so that a blocking signal BLOCK is emitted to block the action of differential protection. The logic diagram shown in FIG. 3 gives details. As FIG. 3 shows, the detected difference currents iₐ, i_{b} and i_{c} of the three phases are sent into a comparator 320 via an OR logic device, for comparison with Iₛₑₜ. The comparison result of comparator 320 is outputted to an AND logic device. At the same time, the waveform symmetry parameter kₘₐₓ is calculated in module 310 by the method shown in FIG. 2. The waveform symmetry parameter kₘₐₓ calculated is sent into a comparator 330 for comparison with the threshold K_{asmy}. The comparison result of comparator 330 is delivered to the AND logic device. If both inputs of the AND logic device are effective, i.e. kₘₐₓ≧K_{asmy} and the difference current of at least one phase is greater than Iₛₑₜ, then the AND logic device outputs an effective blocking signal BLOCK which can be used to block the differential protection of the transformer. Hence instantaneous tripping of the transformer due to the occurrence of a magnetizing inrush current when it is switched on with no load can be avoided. In the example shown in FIG. 3, the comparators 320 and 330 are preferably comparators with hysteresis.

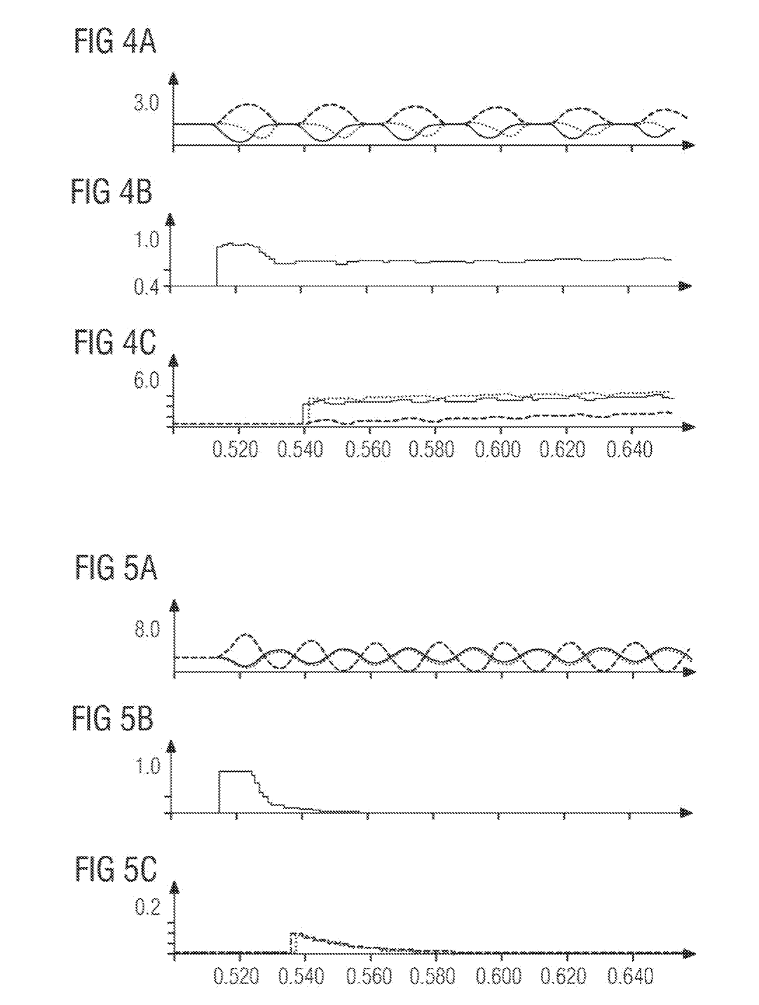

FIGS. 4A-C and FIGS. 5A-C show by way of example the waveforms, waveform symmetry parameters kₘₐₓ and proportions made up by the second harmonic component of a magnetizing inrush current and fault current, respectively. FIG. 4A shows the current waveform of a transformer when it is switched on with no load, wherein the proportion of one AC phase made up by the second harmonic is less than 15%, indicating the waveform of a magnetizing inrush current. It can be seen from FIG. 4A that the waveform of the magnetizing inrush current is asymmetric in at least two phases. FIG. 4B shows the waveform symmetry parameter kₘₐₓ calculated on the basis of the sampled difference currents shown in FIG. 4A by the method shown in FIG. 2. As FIG. 4B shows, kₘₐₓ has a value greater than 0.4. FIG. 4C shows the proportions of the magnetizing inrush current made up by the second harmonic. As FIG. 4C shows, the proportion of one AC phase made up by the second harmonic is less than 15%. In other words, if a judgment is made on whether a magnetizing inrush current has occurred solely on the basis of whether the proportion made up by the second harmonic is less than 15%, then an erroneous judgment is likely, but FIG. 4A can be correctly determined as showing a magnetizing inrush current by the recognition method based on the waveform symmetry parameter kₘₐₓ. Hence differential protection of the transformer can be further blocked, so that it operates normally.

FIG. 5A shows the current waveform of a transformer when it is switched on with no load, wherein a short circuit fault has occurred in phases b and c on the secondary side. It can be seen from FIG. 5A that the waveform of the fault current is substantially symmetric. FIG. 5B shows the waveform symmetry parameter kₘₐₓ calculated on the basis of the sampled difference currents shown in FIG. 5A by the method shown in FIG. 2. As FIG. 5B shows, kₘₐₓ rapidly falls to less than 0.3 after one cycle. In other words, if K_{asmy} is set at approximately 0.3, then once the distinguishing process has begun, a fault current can be correctly distinguished after one period. FIG. 5C shows the proportions of the fault current made up by the second harmonic. As FIG. 5C shows, the proportion made up by the second harmonic only falls below 15% after 2 periods have elapsed since the occurrence of the fault. When FIG. 5B is compared with FIG. 5C, it can be seen that by using the detection method proposed in the present invention, a correct judgment can be made within a shorter time, so that differential protection of the transformer is activated promptly and accurately.

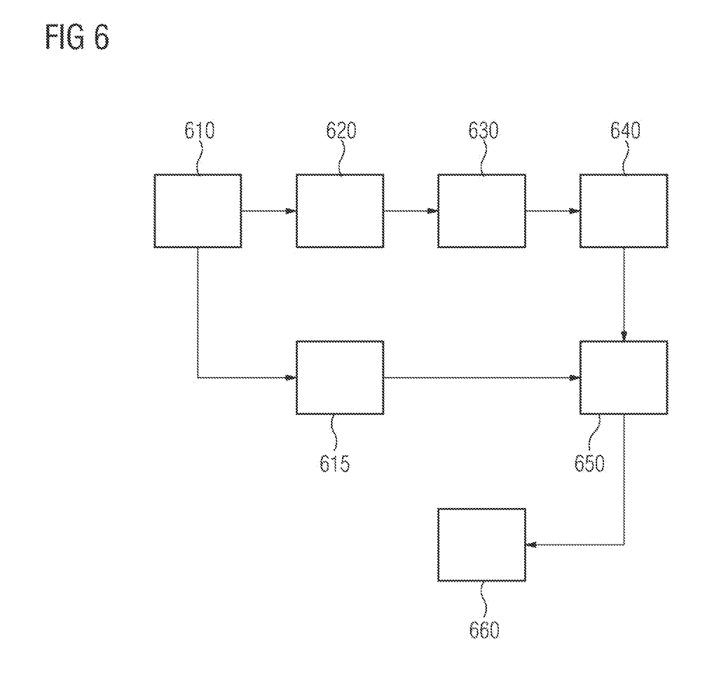

The method and logic shown in FIGS. 2 and 3 above can be realized using software, hardware, or a combination of software and hardware. FIG. 6 is a block diagram of the hardware structure of one embodiment realized using hardware. As FIG. 6 shows, the device for transformer protection comprises: an acquisition unit 610, a first judgment unit 615, a factor calculation unit 620, a maximum value determination unit 630, a symmetry parameter acquisition unit 640, a second judgment unit 650 and a blocking signal generating unit 660. Preferably, the factor calculation unit 620 further comprises a filter unit 621.

As FIG. 6 shows, the acquisition unit 610 samples a difference current iₓ(n) for each AC phase of a transformer, and sends these difference currents into the first judgment unit 615 and the factor calculation unit 620. The first judgment unit 615 determines whether the difference current iₓ(n) of any one of the three AC phases exceeds a predetermined current threshold. For each AC phase, the factor calculation unit 620 calculates factors Ax and Bx for waveform symmetry recognition, on the basis of difference currents sampled within one period. For each type of factor (Ax or Bx), the maximum value determination unit 630 obtains the maximum value of the three factors corresponding to the three AC phases, to serve as a maximum phase factor (Amax, Bmax) of that factor. The symmetry parameter acquisition unit 640 calculates a corresponding waveform symmetry parameter kₘₐₓ, on the basis of the maximum phase factor (Amax, Bmax) obtained. The judgment unit 650 determines that a magnetizing inrush current has not occurred if the waveform symmetry parameter kₘₐₓ meets the waveform symmetry requirement; in turn, if the judgment result of the judgment unit 650 is that the waveform is asymmetric and the judgment result of the first judgment unit is that the difference current of at least one AC phase exceeds the predetermined threshold, then it is determined that a magnetizing inrush current has occurred. The blocking unit 660 blocks differential protection of the transformer when the judgment unit 650 determines that a magnetizing inrush current has occurred.

The various units shown in FIG. 6 may be realized using computing circuits in the form of hardware; they may also be realized using an FPGA, DSP, embeddable programmed microprocessors, or microcontrollers, etc. For instance, the judgment circuit may be realized using a comparator, preferably a comparator with hysteresis. The symmetry parameter acquisition unit may be realized using a divider circuit based on an op-amp, etc. All these solutions are obvious to those skilled in the art.

Those skilled in the art should appreciate that various changes and amendments could be made to the embodiments disclosed above without departing from the substance of the present invention; all such changes and amendments should fall within the scope of protection of the present invention. Therefore the scope of protection of the present invention should be defined by the attached claims.

1-14. (canceled)

15. A method for detecting a magnetizing inrush current of a transformer, which comprises the steps of:
obtaining a difference current iₓ(n) for each one of three AC phases of the transformer, where x=a, b or c;
determining whether the difference current iₓ(n) of any one of the three AC phases exceeds a predetermined current threshold;
calculating, for each of the three AC phases, at least two factors for waveform symmetry recognition, on a basis of difference currents of an AC phase obtained within one period;
for each type of factor, obtaining a maximum value of the three factors corresponding to the three AC phases, to serve as a maximum phase factor of the type of factor;
using a waveform symmetry recognition algorithm to calculate a corresponding waveform symmetry parameter kₘₐₓ based on the maximum phase factor obtained; and
determining that the magnetizing inrush current has occurred, if the waveform symmetry parameter kₘₐₓ meets a requirement for waveform asymmetry and the difference current iₓ(n) of any of the three AC phases exceeds the predetermined current threshold.

16. The method according to claim 15, wherein the step of calculating the at least two factors further comprises filtering out a DC component of a sampled difference current ix(n), to obtain a difference value i′ₓ(n) of the difference current.

17. The method according to claim 16, wherein the two factors used for the waveform symmetry recognition include:
a first factor, which is a function
$$f [ {i}_{x}^{′} ( n ) + {i}_{x}^{′} [ n - \frac{N}{2} ] ]$$
of a sum of two difference current difference values
$$( {i}_{x}^{′} ( n ) , {i}_{x}^{′} [ n - \frac{N}{2} ] )$$
separated by half a period; and
a second factor, which is a function
$$f [ {i}_{x}^{′} ( n ) - {i}_{x}^{′} [ n - \frac{N}{2} ] ]$$
of a difference between two difference current difference values
$$( {i}_{x}^{′} ( n ) , {i}_{x}^{′} [ n - \frac{N}{2} ] )$$
separated by half a period.

18. The method according to claim 17, wherein:
the function used for the first factor is a cumulative value
$$f [ {i}_{x}^{′} ( n ) + {i}_{x}^{′} [ n - \frac{N}{2} ] ] = {\sum }_{n = 0}^{\frac{N}{2} - 1} \vert {i}_{x}^{′} ( n ) + {i}_{x}^{′} ( n - \frac{N}{2} ) \vert$$
of a modulus of a sum over half a period; and
the function used for the second factor is a cumulative value
$$f [ {i}_{x}^{′} ( n ) + {i}_{x}^{′} [ n - \frac{N}{2} ] ] = {\sum }_{n = 0}^{\frac{N}{2} - 1} \vert {i}_{x}^{′} ( n ) + {i}_{x}^{′} ( n - \frac{N}{2} ) \vert$$
of a modulus of the difference over half a period.

19. The method according to claim 17, wherein the waveform symmetry parameter kₘₐₓ is the maximum phase factor of the first factor divided by the maximum phase factor of the second factor.

20. The method according to claim 16, wherein the difference current difference value i′ₓ(n) is found by a forward difference method.

21. A magnetizing inrush current restraint method for a transformer, which comprises the steps of:
determining, by the method according to claim 15, whether a current flowing through the transformer at a present time is a magnetizing inrush current; and
blocking a differential protection of the transformer if the magnetizing inrush current is present.

22. A device for transformer protection, comprising:
an acquisition unit for obtaining a difference current iₓ(n) for each of three AC phases flowing through a transformer;
a first judgment unit for determining whether the difference current iₓ(n) of any one of the three AC phases exceeds a predetermined current threshold;
a factor calculation unit for calculating at least two factors for waveform symmetry recognition for each of the three AC phases, on a basis of difference currents iₓ(n) sampled within one period;
a maximum value determination unit for obtaining a maximum value of three factors corresponding to the three AC phases for each type of factor, to serve as a maximum phase factor of the type of factor;
a symmetry parameter acquisition unit, for calculating a corresponding waveform symmetry parameter kₘₐₓ according to the waveform symmetry recognition, based on the maximum phase factor obtained; and
a second judgment unit for determining that a magnetizing inrush current has occurred if the waveform symmetry parameter kₘₐₓ meets a requirement for waveform asymmetry and said first judgment unit gives a positive result.

23. The device according to claim 22, wherein said factor calculation unit further comprises a filter unit, for filtering out a DC component from a sampled difference current, so as to obtain a difference value of the difference current, and said factor calculation unit calculates the at least two factors on a basis of the difference value of the difference current.

24. The device according to claim 23, wherein the two factors used for the waveform symmetry recognition include:
a first factor, being a cumulative sum over an entire half-cycle of a sum of two difference current difference values separated by half a period; and
a second factor, being a cumulative sum over an entire half-cycle of a difference between two difference current difference values separated by half a period.

25. The device according to claim 22, further comprising a blocking unit for blocking differential protection of the transformer when said second judgment unit determines that the magnetizing inrush current has occurred.

26. A device for transformer protection, comprising:
a microprocessor, for performing operations or processing according to commands;
a memory, for storing the commands which can be executed by said microprocessor, the commands containing program code stored in non-transitory form and configured when loaded into said microprocessor to perform a method for detecting a magnetizing inrush current of a transformer, which comprises the steps of:
obtaining a difference current iₓ(n) for each one of three AC phases of the transformer, where x=a, b or c;
determining whether the difference current iₓ(n) of any one of the three AC phases exceeds a predetermined current threshold;
calculating, for each of the three AC phases, at least two factors for waveform symmetry recognition, on a basis of the difference currents of an AC phase obtained within one period;
for each type of factor, obtaining a maximum value of the three factors corresponding to the three AC phases, to serve as a maximum phase factor of the type of factor;
using a waveform symmetry recognition algorithm to calculate a corresponding waveform symmetry parameter kₘₐₓ based on the maximum phase factor obtained; and
determining that the magnetizing inrush current has occurred, if the waveform symmetry parameter kₘₐₓ meets a requirement for waveform asymmetry and the difference current iₓ(n) of any of the three AC phases exceeds the predetermined current threshold.

27. A computer program product, comprising:
non-transitory code to be executed by a machine, the non-transitory code being used to realize a method according to claim 15 when executed by a machine.

28. A computer recording medium, comprising:
a machine-recordable/readable medium on which non-transitory machine-executable code is stored, the non-transitory machine-executable code being used to realize a method according to claim 15 when executed by a machine.
